(19) United States
(12) Patent Application Publication
(10) Pub. No.: US 2005/0214989 A1
(43) Pub. Date: Sep. 29, 2005

(54) Silicon optoelectronic device

(75) Inventor: Thomas R. Keyser, Plymouth, MN (US)

Correspondence Address: HONEYWELL INTERNATIONAL INC., 101 COLUMBIA ROAD, P O BOX 2245, MORRISTOWN, NJ, 07962-2245, US

(73) Assignee: Honeywell International Inc.

(21) Appl. No.: 10/811,767

(22) Filed: Mar. 29, 2004

(51) Int. Cl. H01L 21/00; H01L 21/84

(52) U.S. Cl. 438/155; 438/164; 438/29; 438/24; 438/149

(57) ABSTRACT

An optoelectronic integrated circuit is fabricated by forming isolation trenches in a SOI structure to form at least first and second areas of silicon, by forming a first silicon island over the first silicon area during a first silicon forming step such that the first silicon island forms at least a portion of an optical device, by forming a second silicon island over the second silicon area during a second silicon forming step such that the first and second silicon forming steps are separate silicon forming steps, and by processing at least the second silicon area to form an electronic device with the second silicon island.

### RELATED APPLICATIONS

The present application contains subject matter similar to the subject matter contained in application Ser. No. 10/755,212 filed on Jan. 12, 2004.

### TECHNICAL FIELD OF THE INVENTION

The present invention relates to optoelectronic devices that combine one or more optical devices and one or more electronic devices on a common semiconductor substrate such as a SOI structure.

### BACKGROUND OF THE INVENTION

Optical devices such as optical waveguides, optical phase modulators, lenses, etc. can be fabricated in Silicon-on-Insulator (SOI) films in configurations that are compatible with integrated circuit structures. One promising implementation, which has been described elsewhere, involves the use of a single crystal SOI film and the formation of a thin poly-silicon upper layer deposited on the SOI film. In this implementation, the thin poly-silicon upper layer is patterned to form a light guiding element or patterned with the SOI film to form SOI/poly composite light guiding features. Poly-silicon alone can also guide light. However, the additional crystalline silicon is desirable to minimize optical losses.

Unfortunately, modern silicon etch systems and processes are optimized so as to prepare vertical features that closely match the dimensions of the masking film. Such vertical features are efficient and necessary for fabricating poly-silicon gates for advanced microelectronics, but the sharp edges of the vertical features can degrade performance in optical device structures such as optical waveguides. Also, patterning using these silicon etch systems and processes can contribute to irregular edges, especially when applied to polycrystalline films.

However, optoelectronic products that combine both optical features and electronic devices are important components in optical signal transmission and processing systems. Such devices have typically been assembled in boards and modules from separate optical and electrical components that can include wave guides, diode sources and detectors, drivers, and amplifiers, using complex and often costly operations.

As noted above, wave guides have been successfully fabricated in Silicon-on-Insulator films. While early wave guides were constructed from silicon films 3 to 4 microns thick, recent advances in SOI material technology have enabled preparation of low-loss wave guides in thinner 0.1 to 0.4 micron layers, typical of those used for high performance, low power electronic device manufacture. At the same time, SOI device and circuit structures have been developed for producing products that operate in the 2.4 to 5.8 GHz range.

With these advances, it now appears that the integration of optical and electronic devices in high performance monolithic (1-10 Gbps+) data transport products may soon be achievable. To realize this goal, several basic structural issues must be resolved.

For efficient light coupling and guiding in 0.1 to 0.3 micron SOI layers, undoped silicon wave guide ribs of equivalent thicknesses are needed. Deposited films with these properties do not, however, satisfy the requirements of electronic device gate electrodes. Because such a film must be maintained free of impurities and must be protected from conductive layers during the fabrication of the optical device, this film does not provide the necessary work function for efficient surface electronic device construction and does not allow for self-aligned implantation or silicidation.

To fabricate an optoelectronic device, it is also desirable to prepare optical features in the SOI layer with near-vertical side walls and to prepare lateral electronic device isolation regions that are sufficiently planar to pattern deep submicron gate and critical layers of the device.

The present invention is directed to certain aspects of the integration of optical devices and electronic devices together as optoelectronic devices.

### SUMMARY OF THE INVENTION

In accordance with one aspect of the present invention, a method of making an optoelectronic integrated circuit comprises the following: forming isolation trenches in a SOI structure to form at least first and second isolated areas of silicon; forming a first silicon island over the first silicon area during a first silicon forming step, wherein the first silicon island forms at least a portion of an optical device; forming a second silicon island over the second silicon area during a second silicon forming step; and, processing at least the second silicon area to form an electronic device with the second silicon island.

In accordance with another aspect of the present invention, a method of making an optoelectronic integrated circuit comprises the following: forming isolation trenches in a SOI structure to form at least first and second isolated areas of silicon; forming a first silicon island over the first silicon area during a first silicon forming step, wherein the first silicon island forms at least a portion of an optical device; forming a second silicon island over the second silicon area during a second silicon forming step, wherein the first and second silicon forming steps are separate silicon forming steps; processing at least the second silicon area to form an electronic device with the second silicon island; forming a blocking oxide over a first portion of the first silicon island so as to leave a second portion of the first silicon island exposed; and, siliciding the second portion of the first silicon island, at least a portion of the second silicon area, and at least of portion of the second silicon island to form contact areas for the optical device and the electronic device.

In accordance with still another aspect of the present invention, an optoelectronic device comprises a SOI structure, an optical device, an electronic device, and first, second, third, fourth, and fifth silicide regions. The SOI structure has at least first and second trenches isolating at least first and second silicon areas. The optical device is formed over at least a portion of the first silicon area and a portion of the first trench, and the optical device includes a first silicon island. The electronic device is formed in and over the second silicon area, and the electronic device includes a poly-silicon island forming a gate region of the electronic device. The first silicide region is formed in the first silicon area, the second silicide region is formed in the first silicon island, and the first and second silicide regions form contacts for the optical device. The third and fourth silicide regions are formed in the second silicon area and a fifth silicide region formed in the second silicon island, and the third, fourth, and fifth silicide regions form contacts for the electronic device.

### BRIEF DESCRIPTION OF THE DRAWINGS

These and other features and advantages of the present invention will become more apparent from a detailed consideration of the invention when taken in conjunction with the drawings in which:

FIG. 1 illustrates a SOI structure having a poly-silicon layer formed thereon;

FIG. 2 illustrates the poly-silicon layer of FIG. 1 after patterning;

FIG. 3 illustrates an oxide layer formed over the exposed silicon layer and the patterned poly-silicon layer shown in FIG. 2;

FIG. 4 illustrates a second conformal amorphous or poly silicon layer deposited over the oxide layer of FIG. 3;

FIG. 5 illustrates the poly-silicon spacers that remain after etching;

FIG. 6 illustrates a first embodiment of an optoelectronic device according to the present invention; and,

FIG. 7 illustrates a second embodiment of an optoelectronic device according to the present invention; and,

FIG. 8 illustrates a third embodiment of an optoelectronic device according to the present invention.

### DETAILED DESCRIPTION

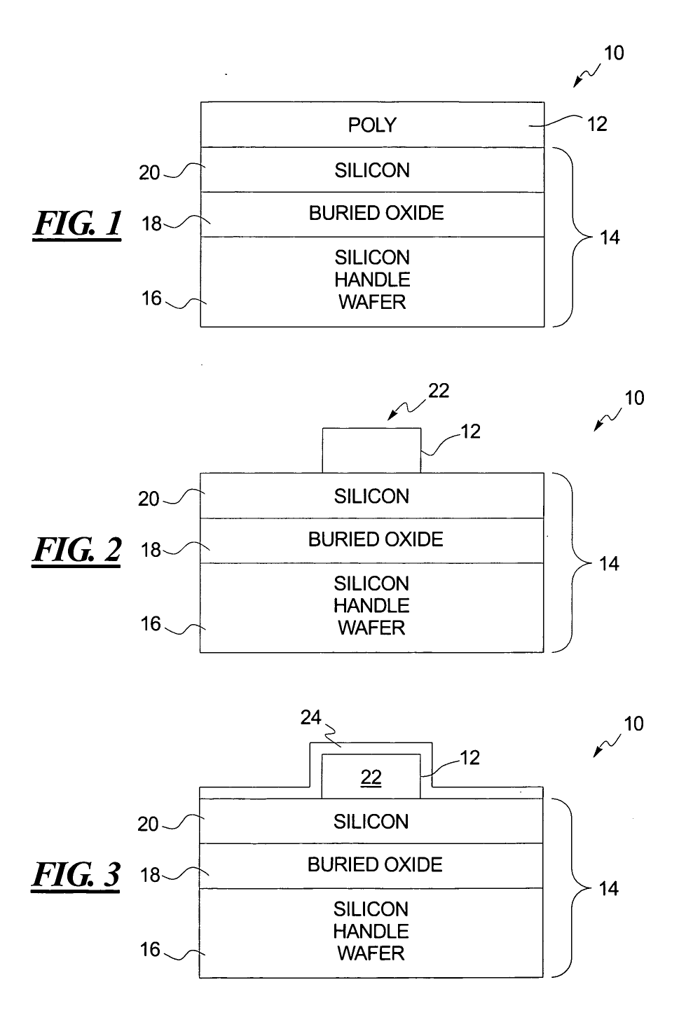

As shown in FIG. 1, a composite optical device 10 is fabricated by first depositing a poly-silicon layer 12 on a SOI structure 14. If desired, a thin dielectric may be provided between the poly-silicon layer 12 and the SOI structure 14 to help confine dopants and to facilitate poly patterning. This dielectric may be a gate oxide and may have a thickness of 30-100 Å. The poly-silicon layer 12 is preferably, although not necessarily, as crystalline as possible to minimize losses and is indexed-matched to the SOI structure 14 to allow uniform expansion of a light beam into the poly-silicon layer 12 from the SOI structure 14.

As is typical, the SOI structure 14 includes a silicon handle wafer 16, a buried oxide layer 18 formed over the silicon handle wafer 16, and a silicon layer 20 formed over the buried oxide layer 18. The silicon layer 20, for example, may be formed from single crystal silicon. Also, the thickness of the poly-silicon layer 12, for example, may be on the order of 1200-1600 Å. Similarly, the thickness of the SOI structure 14, for example, may be on the order of 1200-1600 Å.

As shown in FIG. 2, the poly-silicon layer 12 is patterned to form the appropriate features, such as a poly-silicon rib 22, of a desired optical device. In terms of an optical waveguide, the poly-silicon layer 12 is patterned to form, or to contribute to the formation of, a light guiding rib of the optical waveguide. The poly-silicon rib 22 may be formed, for example, by placing an appropriate mask over the poly-silicon layer 12, and by applying an etchant to remove the unwanted poly-silicon. The poly-silicon layer 12 may be etched selectively with respect to the underlying (oxidized) SOI structure 14. A dry etchant, such as a plasma, may be used for this purpose to maximize control.

As shown in FIG. 3, an oxide layer 24 is formed over the exposed silicon layer 20 and the poly-silicon rib 22. The oxide layer 24 may have a thickness, for example, of approximately 30 to 100 Å. The oxide layer 24 is used as an etch stop during the subsequent etching described below. The oxide layer 24 can also provide gate oxide for other devices formed on the SOI structure 14. The oxide layer 24, however, may be omitted if desired. Moreover, other dielectric materials such as silicon nitride could be used in place of the oxide in the oxide layer 24.

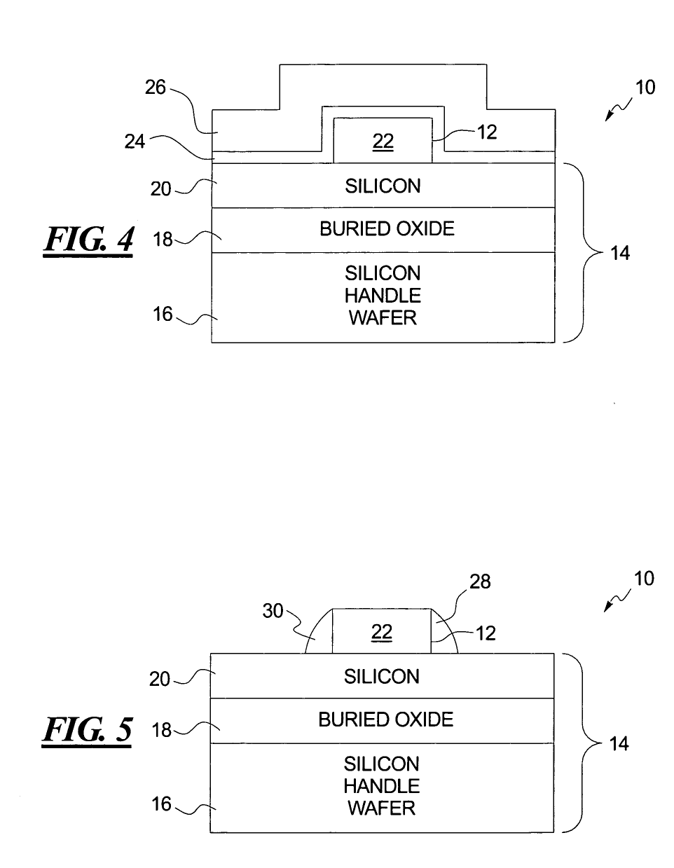

As shown in FIG. 4, a conformal amorphous or poly-silicon layer 26 is deposited over the oxide layer 24. The thickness of the conformal amorphous or poly-silicon layer 26, for example, may be on the order of 2000 to 3000 Å. As shown in FIG. 5, the conformal amorphous or poly-silicon layer 26 is anisotropically etched until the material is removed from all horizontal surfaces, leaving amorphous or poly-silicon spacers 28 and 30 along the side walls of the original poly-silicon rib 22. These amorphous or poly-silicon spacers 28 and 30 round the corners of the poly-silicon rib 22, thus reducing the optical losses and improving the performance of the optical device 10.

The process described above does not rely on complex isotropic/anisotropic etching, oxidation, potentially damaging chemical mechanical planarization (CMP), or physical sputtering processes that are available in a typical fabrication facility. The process described above instead utilizes simple poly or amorphous silicon deposition and anisotropic etching processes to create a composite silicon structure with the necessary rounded edges.

Producing an optical waveguide or other optical device with rounded corners and with acceptable control and repeatability in a device compatible process flow is not easily accomplished by modern fabrication tools. Silicon etchers are designed and conditioned to etch vertical wall features. Older resist erosion techniques utilize oxygen containing chemistries that are not compatible with poly-silicon to oxide selectivity requirements. Wet-dry etching processes require special masks and protection for the silicon regions, and suffer from poor control and edge uniformity. Oxidation processes do not produce the desired rounding. CMP techniques are subject to pattern density variations.

The spacers and the process of forming these spacers as described herein, however, produces the desired rounded corners and/or reduces or eliminates the problems of the other processes described herein.

The spacers can be implemented along portions of the SOI or SOI/poly wave guide to reduce edge non-uniformities and round corners to minimize losses. Spacers are also useful for facilitating light transmission from a SOI waveguide to a composite SOI/poly-silicon waveguide.

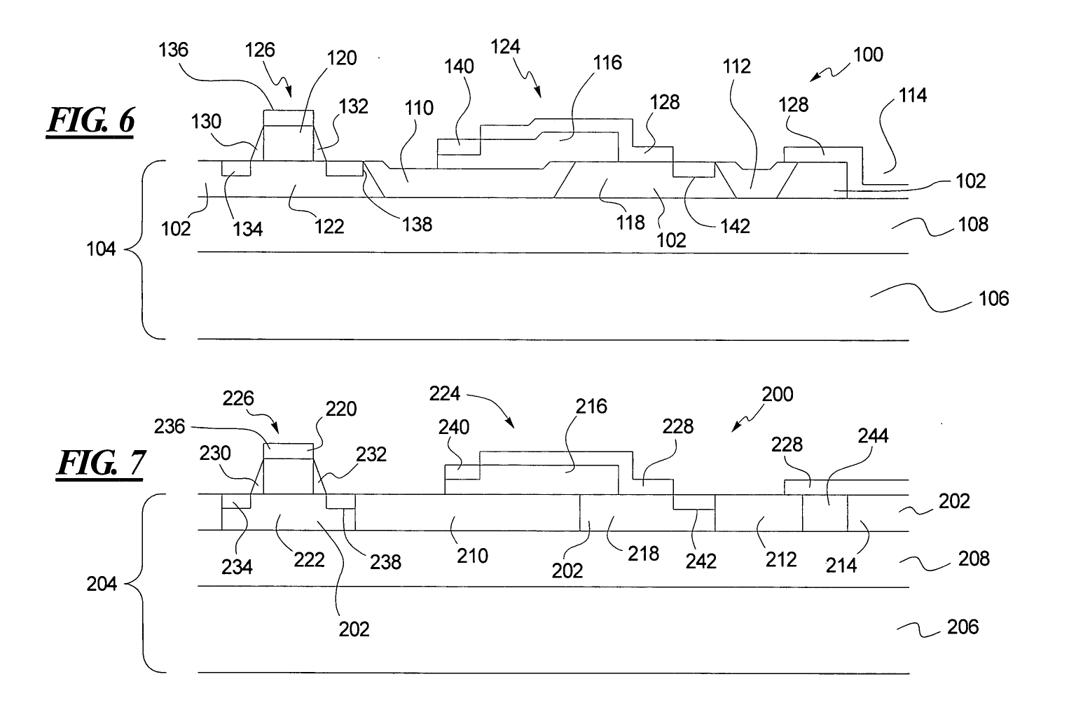

A first optoelectronic device 100 is shown in FIG. 6. The first optoelectronic device 100 is implemented using a LOCOS isolation process in an upper silicon layer 102 of an SOI structure 104 having a silicon handle wafer 106, a buried oxide layer 108 formed over the silicon handle wafer 106, and the upper silicon layer 102 formed over the buried oxide layer 108. The upper silicon layer 102, for example, may be formed from single crystal silicon. The upper silicon layer 102 is partially etched in the areas of isolation trenches 110 and 112. For example, the upper silicon layer 102 may be etched in the areas of the isolation trenches 110 and 112 so that approximately 50% of the silicon remains in these areas. The silicon that remains in the isolation trenches 110 and 112 is oxidized, such as through a mask, to form the isolation trenches 110 and 112. As shown in FIG. 6, the walls of the isolation trenches 110 and 112 are sloped. Also, the isolation trenches 110 and 112 may be relatively planar recessed or semi-recessed LOCOS isolations.

A vertical etch can then be selectively applied to form an optical edge 114 in the form of a vertical side wall for an optical feature such as a lens or grating. If desired, a thin dielectric, such as silicon dioxide, may be formed over the exposed silicon of the remaining portions of the upper silicon layer 102 to separate the SOI structure 104 from the silicon layers subsequently deposited and to protect the SOI structure 104 from attack when the subsequently deposited silicon layers are patterned.

A first poly-silicon 116 is deposited or otherwise formed so that it extends over a portion of the isolation trench 110 and over a portion of a silicon island 118 that is defined between the isolation trenches 110 and 112. The first poly-silicon 116, for example, may be thin such as between 0.1 micron and 0.2 micron and may remain undoped during further processing. The first poly-silicon 116 may alternatively be amorphous silicon. The residual oxide formed over the SOI structure 104 is then stripped from the area where an electronic device is to be formed so as to prepare that area for gate oxide growth. A subsequent oxidation step grows the necessary gate dielectric and a protective layer over the first poly-silicon 116.

A second poly-silicon 120 is deposited or otherwise formed over a silicon island 122 that is defined at least on one side by the isolation trench 110. The second poly-silicon 120, for example, may have a thickness between 0.3 micron and 0.4 micron. The second poly-silicon 120 may be suitably doped and may alternatively be amorphous silicon. The first poly-silicon 116 and the second poly-silicon 120 may themselves be referred to as silicon islands, or alternatively as poly-silicon islands. The first poly-silicon 116 and the second poly-silicon 120 may be formed during different and independent poly-silicon forming steps.

The first poly-silicon 116 may form an optical device 124 such as an optical waveguide or an optical phase modulator that may be patterned using, for example, conventional photo-resist masking and implantation techniques. The second poly-silicon 120 may form a gate of an electronic device 126 such as a transistor where source and drain regions are suitably formed in the silicon island 122 using conventional photo-resist masking and implantation techniques.

A blocking oxide 128 is deposited and anisotropically etched through a mask to form side wall spacers 130 and 132 along the second poly-silicon 120 that will define the edge of the source-drain implants of the electronic device 126 and to expose silicon in silicide regions 134, 136, 138, 140, and 142. The mask employed during the anisotropic etch prevents the removal of the blocking oxide 128 from the relevant portions of the optical device 124, the optical edge 114, and any other silicon features where it is desired to prevent unwanted silicidation. The silicide regions 134, 136, 138, 140, and 142 may then be conventionally formed. The first optoelectronic device 100 may then be covered with a thick dielectric layer to isolate it from subsequent metallization/interconnection steps. The silicide regions 134, 136, and 138 form electrical contacts for the electronic device 126, and the silicide regions 140 and 142 form electrical contacts for the optical device 124.

Although not shown, the first poly-silicon 116 may be provided with poly-silicon spacers as described above. For example, poly-silicon spacers alongside the first poly-silicon 116 may be formed as a result of the formation of the second poly-silicon 120.

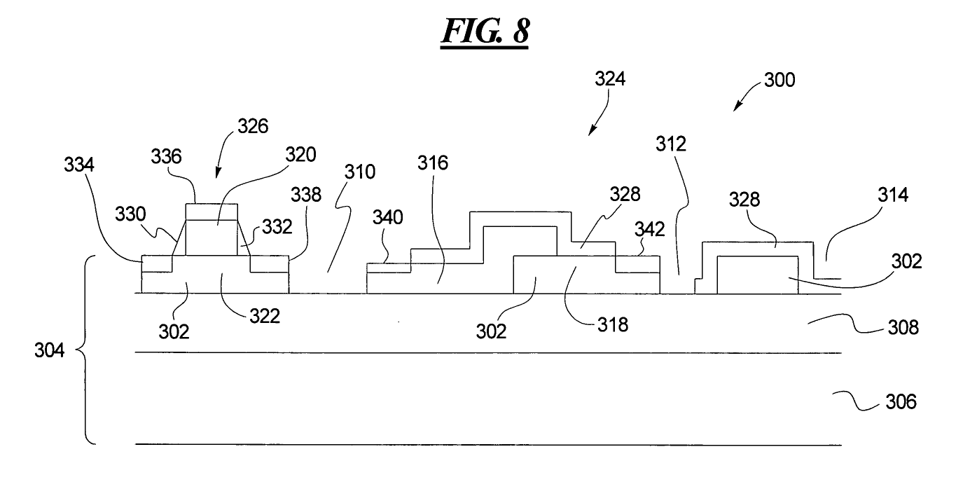

A second optoelectronic device 200 is shown in FIG. 7. The second optoelectronic device 200 is implemented using a shallow trench isolation process in an upper silicon layer 202 of an SOI structure 204 having a silicon handle wafer 206, a buried oxide layer 208 formed over the silicon handle wafer 206, and the upper silicon layer 202 formed over the buried oxide layer 208. The upper silicon layer 202, for example, may be formed from single crystal silicon.

CMP etch-stop layers, e.g. oxide and nitride, and masking are applied to the upper silicon layer 202, and the upper silicon layer 202 is then vertically etched to form recesses in the areas of isolation trenches 210, 212, and 214. Silicon oxide is then used to fill the recesses to a level higher than the surface of the CMP etch-stop layer. The resulting structure is then polished with CMP back to the etch stop layer and subjected to acid etching reagents to remove the residual etch-stop layers. Accordingly, the isolation trenches 210, 212, and 214 are so formed. As shown in FIG. 7, the walls of the isolation trenches 210, 212, and 214 are vertical. The vertical side wall of the isolation trench 214 forms an optical feature such as an optical wall of a lens or grating.

If desired, a thin dielectric, such as silicon dioxide, may be formed over the exposed silicon of the remaining portions of the upper silicon layer 202 to separate the SOI structure 204 from the silicon layers subsequently deposited and to protect the SOI structure 204 from attack when the subsequently deposited silicon layers are patterned.

A first poly-silicon 216 is deposited or otherwise formed so that it extends over a portion of the isolation trench 210 and over a portion of a silicon island 218 that is defined between the isolation trenches 210 and 212. The first poly-silicon 216, for example, may be thin such as between 0.1 micron and 0.2 micron, and may remain undoped during further processing. The first poly-silicon 216 may alternatively be amorphous silicon. The residual oxide formed over the SOI structure 204 is stripped from the area where an electronic device is to be formed so as to prepare that area for gate oxide growth. A subsequent oxidation step grows the necessary gate dielectric and a protective layer over the first poly-silicon 216.

A second poly-silicon 220 is deposited or otherwise formed over a silicon island 222 that is defined at least on one side by the isolation trench 210. The second poly-silicon 220, for example, may have a thickness between 0.3 micron and 0.4 micron. The second poly-silicon 220 may be suitably doped and may alternatively be amorphous silicon. The first poly-silicon 216 and the second poly-silicon 220 may themselves be referred to as silicon islands, or alternatively as poly-silicon islands. The first poly-silicon 216 and the second poly-silicon 220 may be formed during different and independent poly-silicon forming steps.

The first poly-silicon 216 may form an optical device 224 such as an optical waveguide or an optical phase modulator that may be patterned using, for example, conventional photo-resist masking and implantation techniques. The second poly-silicon 220 may form a gate of an electronic device 226 such as a transistor where source and drain regions are suitably formed in the silicon island 222 using conventional photo-resist masking and implantation techniques.

A blocking oxide 228 is then deposited and anisotropically etched through a block mask to form side wall spacers 230 and 232 along the second poly-silicon 220 that will define the edge of the source-drain implants of the electronic device 226 and to define silicide regions 234, 236, 238, 240, and 242. The mask employed during the anisotropic etch prevents the removal of the blocking oxide 228 from the relevant portions of the optical device 224, an optical edge defined by the isolation trench 214, and any silicon features where it is desired to prevent unwanted silicidation. The silicide regions 234, 236, 238, 240, and 242 may then be conventionally formed. The second optoelectronic device 200 is then covered with a thick dielectric layer to isolate it from subsequent metallization/interconnection steps. The silicide regions 234, 236, and 238 form electrical contacts for the electronic device 226, and the silicide regions 240 and 242 form electrical contacts for the optical device 224.

Although not shown, the first poly-silicon 216 may be provided with poly-silicon spacers as described above. For example, poly-silicon spacers alongside the first poly-silicon 216 may be formed as a result of the formation of the second poly-silicon 220.

Thus, according to the exemplary description above, processing steps and/or structures can be used to produce a set of merged optoelectronic devices that satisfy one or more of the diverse requirements of each device type. Separate silicon layers may be used to fabricate the optical and electronic devices and to independently optimize the properties of each, as desired. An oxide film may be used to create sidewall spacers for the electrical devices and to form a blocking layer to prevent certain devices such as optical devices from reacting with the metal films during silicide formation. A flexible modular isolation approach also can be used to create the necessary optical surfaces and to isolate the various devices. The optical device elements can be created using a vertical wall anisotropic silicon etch process, while electronic device isolation may be implemented, for example, using either the same vertical trench process in a shallow trench isolation (STI) scheme or an alternative LOCOS-based process.

As shown in FIG. 7, a silicon island 244 is formed between the isolation trenches 212 and 214.

A third optoelectronic device 300 is shown in FIG. 8. The third optoelectronic device 300 is implemented using a shallow trench isolation process in an upper silicon layer 302 of an SOI structure 304 having a silicon handle wafer 306, a buried oxide layer 308 formed over the silicon handle wafer 306, and the upper silicon layer 302 formed over the buried oxide layer 308. The upper silicon layer 302, for example, may be formed from single crystal silicon.

CMP etch-stop layers, e.g. oxide and nitride, and masking are applied to the upper silicon layer 302, and the upper silicon layer 302 is then vertically etched to form recesses in the areas of isolation trenches 310, 312, and 314. Except as shown in FIG. 8, the isolation trenches 310, 312, and 314 may remain empty of dielectric or other materials by suitable masking during subsequent processing. The vertical side wall of the isolation trench 314 forms an optical feature such as an optical wall of a lens or grating.

If desired, a thin dielectric, such as silicon dioxide, may be formed over the exposed silicon of the remaining portions of the upper silicon layer 302 to separate the SOI structure 304 from the silicon layers subsequently deposited and to protect the SOI structure 304 from attack when the subsequently deposited silicon layers are patterned.

A first poly-silicon 316 is deposited or otherwise formed so that it extends over a portion of the buried oxide layer 308 and over a portion of a silicon island 318 that remains after the upper silicon layer 302 is etched to form the isolation trenches 310 and 312. The first poly-silicon 316, for example, may be thin such as between 0.1 micron and 0.2 micron, and may remain undoped during further processing. The first poly-silicon 316 may alternatively be amorphous silicon. A subsequent oxidation step grows the necessary gate dielectric and a protective layer over the first poly-silicon 316.

A second poly-silicon 320 is deposited or otherwise formed over a silicon island 322 that is defined at least on one side by the isolation trench 310. The second poly-silicon 320, for example, may have a thickness between 0.3 micron and 0.4 micron. The second poly-silicon 320 may be suitably doped and may alternatively be amorphous silicon. The first poly-silicon 316 and the second poly-silicon 320 may themselves be referred to as silicon islands, or alternatively as poly-silicon islands. The first poly-silicon 316 and the second poly-silicon 320 may be formed during different and independent poly-silicon forming steps.

The first poly-silicon 316 may form an optical device 324 such as an optical waveguide or an optical phase modulator that may be patterned using, for example, conventional photo-resist masking and implantation techniques. The second poly-silicon 320 may form a gate of an electronic device 326 such as a transistor where source and drain regions are suitably formed in the silicon island 322 using conventional photo-resist masking and implantation techniques.

A blocking oxide 328 is then deposited and anisotropically etched through a block mask to form side wall spacers 330 and 332 along the second poly-silicon 320 that will define the edge of the source-drain implants of the electronic device 326 and to define silicide regions 334, 336, 338, 340, and 342. The mask employed during the anisotropic etch prevents the removal of the blocking oxide 328 from the relevant portions of the optical device 324, an optical edge defined by the isolation trench 314, and any silicon features where it is desired to prevent unwanted silicidation. The silicide regions 334, 336, 338, 340, and 342 may then be conventionally formed. The third optoelectronic device 300 is then covered with a thick dielectric layer to isolate it from subsequent metallization/interconnection steps. The silicide regions 334, 336, and 338 form electrical contacts for the electronic device 326, and the silicide regions 340 and 342 form electrical contacts for the optical device 324.

Thus, according to the exemplary description above, processing steps and/or structures can be used to produce a set of merged optoelectronic devices that satisfy one or more of the diverse requirements of each device type. Separate silicon layers may be used to fabricate the optical and electronic devices and to independently optimize the properties of each, as desired. An oxide film may be used to create sidewall spacers for the electrical devices and to form a blocking layer to prevent certain devices such as optical devices from reacting with the metal films during silicide formation. A flexible modular isolation approach also can be used to create the necessary optical surfaces and to isolate the various devices. The optical device elements can be created using a vertical wall anisotropic silicon etch process, while electronic device isolation may be implemented, for example, using either the same vertical trench process in a shallow trench isolation (STI) scheme or an alternative LOCOS-based process.

Certain modifications of the present invention have been discussed above. Other modifications will occur to those practicing in the art of the present invention. For example, the present invention can be used in connection with optical devices, other than optical waveguides, such as optical modulators, optical switches, etc.

Also, the isolation trenches 110 and 112 may be either separate isolation trenches of any desired geometric shapes or a continuous trench of any desired geometric shape. Similarly, the isolation trenches 210, 212, 310, and 312 may be either separate isolation trenches of any desired geometric shapes or a continuous trench of any desired geometric shape.

Moreover, the present invention has been described above in relation to an SOI structure having a silicon layer, a buried oxide layer, and silicon handle wafer. The buried oxide layer can alternatively be formed from other insulation materials such as sapphire.

Accordingly, the description of the present invention is to be construed as illustrative only and is for the purpose of teaching those skilled in the art the best mode of carrying out the invention. The details may be varied substantially without departing from the spirit of the invention, and the exclusive use of all modifications which are within the scope of the appended claims is reserved.

1. A method of making an optoelectronic integrated circuit comprising:
forming isolation trenches in a SOI structure to form at least first and second isolated areas of silicon;
forming a first silicon island over the first silicon area during a first silicon forming step, wherein the first silicon island forms at least a portion of an optical device;
forming a second silicon island over the second silicon area during a second silicon forming step; and,
processing at least the second silicon area to form an electronic device with the second silicon island.

2. The method of claim 1 wherein the first silicon island comprises a poly-silicon island.

3. The method of claim 1 wherein the second silicon island comprises a poly-silicon island.

4. The method of claim 1 wherein the first silicon island comprises a first poly-silicon island, and wherein the second silicon island comprises a second poly-silicon island.

5. The method of claim 1 wherein the first silicon island comprises an amorphous silicon island.

6. The method of claim 1 wherein the second silicon island comprises an amorphous silicon island.

7. The method of claim 1 wherein the first silicon island comprises a first amorphous silicon island, and wherein the second silicon island comprises a second amorphous silicon island.

8. The method of claims 1 wherein the forming of isolation trenches comprises forming LOCOS based dielectric isolation trenches.

9. The method of claims 8 further comprising vertically etching the SOI structure so as to form a vertical wall of a further optical device.

10. The method of claims 9 wherein the LOCOS based dielectric isolation trenches have sloped side walls.

11. The method of claims 1 wherein the forming of isolation trenches comprises forming shallow trench dielectric isolation trenches having vertical side walls.

12. The method of claims 11 further comprising vertically etching the SOI structure so as to form a vertical wall of a further optical device.

13. The method of claims 1 further comprising vertically etching the SOI structure so as to form a vertical wall of a further optical device.

14. The method of claim 1 wherein the forming of isolation trenches in a SOI structure comprises forming of an isolation trench at least partially filled with a dielectric, and wherein the forming of a first silicon island over the first silicon area comprises forming the first silicon island over the first silicon area and the dielectric.

15. The method of claim 1 wherein the forming of isolation trenches in a SOI structure comprises forming of an isolation trench so as to substantially expose a buried insulation layer of the SOI structure, and wherein the forming of a first silicon island over the first silicon area during a first silicon forming step comprises forming the first silicon island in over the first silicon area and the exposed buried insulation layer.

16. A method of making an optoelectronic integrated circuit comprising:
forming isolation trenches in a SOI structure to form at least first and second isolated areas of silicon;
forming a first silicon island over the first silicon area during a first silicon forming step, wherein the first silicon island forms at least a portion of an optical device;
forming a second silicon island over the second silicon area during a second silicon forming step, wherein the first and second silicon forming steps are separate silicon forming steps;
processing at least the second silicon area to form an electronic device with the second silicon island;
forming a blocking oxide over a first portion of the first silicon island so as to leave a second portion of the first silicon island exposed; and,
siliciding the second portion of the first silicon island, at least a portion of the second silicon area, and at least of portion of the second silicon island to form contact areas for the optical device and the electronic device.

17. The method of claim 16 wherein the first silicon island comprises a poly-silicon island.

18. The method of claim 16 wherein the second silicon island comprises a poly-silicon island.

19. The method of claim 16 wherein the first silicon island comprises a first poly-silicon island, and wherein the second silicon island comprises a second poly-silicon island.

20. The method of claim 16 wherein the first silicon island comprises an amorphous silicon island.

21. The method of claim 16 wherein the second silicon island comprises an amorphous silicon island.

22. The method of claim 16 wherein the first silicon island comprises a first amorphous silicon island, and wherein the second silicon island comprises a second amorphous silicon island.

23. The method of claims 16 wherein the forming of isolation trenches comprises forming LOCOS based dielectric isolation trenches.

24. The method of claims 23 further comprising vertically etching the SOI structure so as to form a vertical wall of a further optical device.

25. The method of claims 24 wherein the LOCOS based dielectric isolation trenches have sloped side walls.

26. The method of claims 16 wherein the forming of isolation trenches comprises forming shallow trench dielectric isolation trenches having vertical side walls.

27. The method of claims 26 further comprising vertically etching the SOI structure so as to form a vertical wall of a further optical device.

28. The method of claims 16 further comprising vertically etching the SOI structure so as to form a vertical wall of a further optical device.

29. The method of claim 16 wherein the forming of a blocking oxide comprises forming spacers along the second silicon island.

30. The method of claim 16 wherein the forming of isolation trenches in a SOI structure comprises forming of an isolation trench at least partially filled with a dielectric, and wherein the forming of a first silicon island over the first silicon area comprises forming the first silicon island over the first silicon area and the dielectric.

31. The method of claim 16 wherein the forming of isolation trenches in a SOI structure comprises forming of an isolation trench so as to substantially expose a buried insulation layer of the SOI structure, and wherein the forming of a first silicon island over the first silicon area during a first silicon forming step comprises forming the first silicon island in over the first silicon area and the exposed buried insulation layer.

32. An optoelectronic device comprising:
a SOI structure having at least first and second trenches isolating at least first and second silicon areas;
an optical device formed over at least a portion of the first silicon area and a portion of the first trench, the optical device including a first silicon island;
an electronic device formed in and over the second silicon area, the electronic device including a second silicon island forming a gate region of the electronic device;
a first silicide region formed in the first silicon area and a second silicide region formed in the first silicon island, wherein the first and second silicide regions form contacts for the optical device; and,
third and fourth silicide regions formed in the second silicon area and a fifth silicide region formed in the second silicon island, wherein the third, fourth, and fifth silicide regions form contacts for the electronic device.

33. The optoelectronic device of claim 32 wherein the first silicon island comprises a poly-silicon island.

34. The optoelectronic device of claim 32 wherein the second silicon island comprises a poly-silicon island.

35. The optoelectronic device of claim 32 wherein the first silicon island comprises a first poly-silicon island, and wherein the second silicon island comprises a second poly-silicon island.

36. The optoelectronic device of claim 32 wherein the first silicon island comprises an amorphous silicon island.

37. The optoelectronic device of claim 32 wherein the second silicon island comprises an amorphous silicon island.

38. The optoelectronic device of claim 32 wherein the first silicon island comprises a first amorphous silicon island, and wherein the second silicon island comprises a second amorphous silicon island.

39. The optoelectronic device of claims 32 wherein the first and second trenches comprise corresponding LOCOS based first and second dielectric trenches.

40. The optoelectronic device of claims 39 further comprising a third trench, wherein the third trench forms a vertical wall of a third silicon island of the SOI structure, and wherein the vertical wall comprises a further optical device.

41. The optoelectronic device of claims 40 wherein the LOCOS based first and second dielectric trenches have sloped side walls.

42. The optoelectronic device of claims 32 wherein the first and second trenches are formed as corresponding first and second shallow dielectric trenches having vertical side walls.

43. The optoelectronic device of claims 42 further comprising a third trench, wherein the third trench forms a vertical wall of a third silicon island of the SOI structure, and wherein the vertical wall comprises a further optical device.

44. The optoelectronic device of claims 32 further comprising a third trench, wherein the third trench forms a vertical wall of a third silicon island of the SOI structure, and wherein the vertical wall comprises a further optical device.

45. The optoelectronic device of claim 32 further comprising spacers along the second silicon island.

46. The method of claim 1 wherein the first and second silicon forming steps are separate silicon forming steps.
